(19) United States
(12) Patent Application Publication
(10) Pub. No.: US 2025/0096786 A1
(43) Pub. Date: Mar. 20, 2025

(54) AUXILIARY CIRCUIT FOR ESTIMATING MILLER PLATEAU, AND DRIVING CIRCUIT AND POWER CONVERSION SYSTEM INCLUDING THE SAME

(71) Applicant: SAMSUNG ELECTRONICS CO., LTD., Suwon-si (KR)

(72) Inventors: Taehwang KONG, Suwon-si (KR); Yeunhee HUH, Suwon-si (KR)

(73) Assignee: SAMSUNG ELECTRONICS CO., LTD., Suwon-si (KR)

(21) Appl. No.: 18/678,867

(22) Filed: May 30, 2024

(30) Foreign Application Priority Data
Sep. 18, 2023 (KR) 10-2023-0124254

(51) Int. Cl. H03K 17/0412; H02M 1/08; H02M 3/158; H03K 17/16

(52) U.S. Cl. CPC H03K 17/04123; H02M 1/083; H02M 3/158; H03K 17/162

(57) ABSTRACT

Provided is an auxiliary circuit configured to estimate a Miller plateau of a power transistor in a power conversion system, the auxiliary circuit including a filtering circuit electrically connected to a switching node of the power conversion system and configured to filter a voltage of the switching node, and a sensing circuit electrically connected to an output node of the filtering circuit and configured to detect whether the voltage of the switching node reaches a predetermined voltage level based on a voltage of the output node of the filtering circuit.

### CROSS-REFERENCE TO RELATED APPLICATION

This application claims priority to Korean Patent Application No. 10-2023-0124254, filed on Sep. 18, 2023, in the Korean Intellectual Property Office, the disclosure of which is incorporated by reference herein in its entirety.

### BACKGROUND

### 1. Field

Embodiments of the present disclosure relate to electronic circuits, and more particularly, to electronic circuits for estimating a Miller plateau of a power transistor.

### 2. Description of Related Art

When a power transistor operates at a relatively high speed, a sudden current pulse may occur in a power supply, causing an electro-magnetic interference (EMI) in a power converter. EMI may affect peripheral devices or circuits of the power converter. Accordingly, the consideration of EMI requires the need for compliance testing to ensure adherence to international standards.

Additionally, when the power transistor operates at a relatively high speed, other power transistors in an off state may be affected and a false turn-on may occur. The power conversion efficiency of the power converter may be reduced due to false turn-on.

### SUMMARY

One or more example embodiments provide an auxiliary circuit for estimating a Miller plateau, and a driving circuit and power conversion system including the same.

Additional aspects will be set forth in part in the description which follows and, in part, will be apparent from the description, or may be learned by practice of the presented embodiments of the disclosure.

According to an aspect of an example embodiment, there is provided an auxiliary circuit configured to estimate a Miller plateau of a power transistor in a power conversion system, the auxiliary circuit including a filtering circuit electrically connected to a switching node of the power conversion system and configured to filter a voltage of the switching node, and a sensing circuit electrically connected to an output node of the filtering circuit and configured to detect whether the voltage of the switching node becomes equal to a predetermined voltage level based on a voltage of the output node of the filtering circuit.

An output node of the sensing circuit may be electrically connected to a gate driver for the power transistor.

The sensing circuit may be further configured to detect a zero-crossing of the voltage of the switching node.

The sensing circuit may be further configured to detect a zero-crossing of the voltage of the switching node from a negative direction to a positive direction.

The sensing circuit may be further configured to output a low state output signal or a high state output signal based on a detection result, and the sensing circuit may be further configured to change the output signal from a low state to a high state based on the voltage of the switching node reaching the predetermined voltage level.

The sensing circuit may include a first transistor including a first emitter terminal electrically connected to a ground voltage node, and a second transistor including a second emitter terminal electrically connected to the output node of the filtering circuit and a gate terminal electrically connected to the gate terminal of the first transistor.

A size of the first transistor may be equal to a size of the second transistor.

The output node of the sensing circuit may be electrically connected to a collector terminal of the second transistor.

The sensing circuit may further include a current source, and a current mirror circuit configured to mirror and supply an output current of the current source to the first transistor and the second transistor.

The sensing circuit further may include a third transistor that includes a third emitter terminal electrically connected to the output node of the filtering circuit and a gate terminal electrically connected to the gate terminal of the second transistor.

A size of the second transistor may be less than a size of the first transistor, and a size of the third transistor may be equal to the size of the first transistor.

The sensing circuit may further include a switch configured to control an electrical connection between a collector terminal of the second transistor and a collector terminal of the third transistor.

The switch may be configured to operate in an on state based on the power transistor being in an off state and to operate in an off state based on the power transistor being in an on state.

The filtering circuit may include a high pass filter configured to filter a voltage of the switching node.

According to another aspect of an example embodiment, there is provided a driving circuit for a power conversion system, the driving circuit including an auxiliary circuit configured to estimate a Miller plateau of a power transistor, and a gate driver electrically connected to the auxiliary circuit, wherein the auxiliary circuit includes a filtering circuit electrically connected to a switching node of the power conversion system and configured to filter a voltage of the switching node, and a sensing circuit electrically connected to an output node of the filtering circuit and configured to detect whether the voltage of the switching node becomes equal to a predetermined voltage level based on the voltage of the output node of the filtering circuit, and wherein the gate driver is configured to drive the power transistor based on a detection result of the sensing circuit.

The sensing circuit may be further configured to output a low state output signal or a high state output signal based on the detection result, and the gate driver may be further configured to drive the power transistor based on the output signal of the sensing circuit.

The gate driver may be further configured to drive the power transistor to increase the gate voltage of the power transistor by a first increment amount based on the output signal of the sensing circuit being in the low state, and to drive the power transistor to increase the gate voltage of the power transistor by a second increment amount greater than the first increment amount based on the output signal of the sensing circuit changing from the low state to the high state.

According to yet another aspect of an example embodiment, there is provided a power conversion system including a first power transistor and a second power transistor electrically connected to a switching node, an auxiliary circuit configured to estimate a Miller plateau of the first power transistor, and a gate driver electrically connected to the auxiliary circuit, wherein the auxiliary circuit includes a filtering circuit electrically connected to the switching node and configured to filter a voltage of the switching node, and a sensing circuit electrically connected to an output node of the filtering circuit and configured to detect whether the voltage of the switching node crosses a predetermined voltage level based on the voltage of the output node of the filtering circuit, and wherein the gate driver is configured to drive the first power transistor and the second power transistor based on a detection result of the sensing circuit.

The sensing circuit may be further configured to output a low state output signal or a high state output signal based on the detection result, and the gate driver may be further configured to drive the first power transistor based on the output signal of the sensing circuit.

The sensing circuit may be further configured to output a low state output signal or a high state output signal based on the detection result, and the gate driver may be configured to control a gate resistance of the second power transistor based on the output signal of the sensing circuit.

### BRIEF DESCRIPTION OF THE DRAWINGS

The above and other aspects, features, and advantages of example embodiments will be more apparent from the following description taken in conjunction with the accompanying drawings, in which:

FIG. 1A is a circuit diagram of a buck converter according to an example embodiment;

FIG. 1B is a graph illustrating a Miller plateau and false turn-on according to an example embodiment;

FIGS. 2 and 3 are circuit diagrams of power conversion systems according to example embodiments;

FIG. 4 is a diagram for explaining an auxiliary circuit according to an example embodiment;

FIG. 5 is a circuit diagram of a filtering circuit according to an example embodiment; and

FIGS. 6, 7A, 7B, and 7C are circuit diagrams of sensing circuits according to example embodiments.

### DETAILED DESCRIPTION

Reference will now be made in detail to embodiments, examples of which are illustrated in the accompanying drawings, wherein like reference numerals refer to like elements throughout. In this regard, the example embodiments may have different forms and should not be construed as being limited to the descriptions set forth herein. Accordingly, the example embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

Hereinafter, various embodiments of the disclosure will be described with reference to the accompanying drawings.

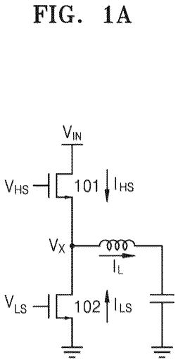

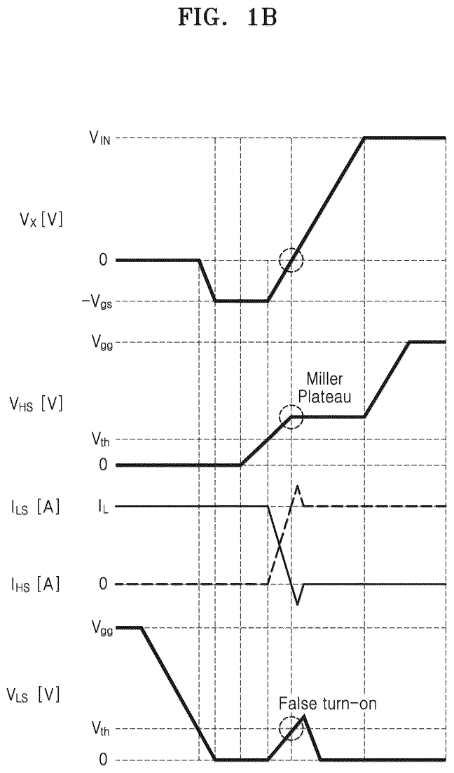

FIG. 1A is a circuit diagram of a buck converter according to an embodiment. FIG. 1B is a graph illustrating a Miller plateau and false turn-on according to an embodiment.

Referring to FIGS. 1A and 1B, when a gate voltage V_{LS} of a lower power transistor 102 falls below a threshold voltage Vₜₕ, a switching node voltage V_{X} begins to decrease and becomes lower than 0V. The voltage V_{X} of the switching node decreases to −V_{gs}. Here, V_{gs} is a gate-source voltage of the lower power transistor 102.

In addition, when a gate voltage V_{LS} of a lower power transistor 102 falls below a threshold voltage Vₜₕ, an upper power transistor 101 begins transitioning from an off state to an on state, and a gate voltage V_{HS} of the upper power transistor 101 begins to increase. When the gate voltage V_{HS} of the upper power transistor 101 becomes equal to and crosses the threshold voltage Vₜₕ, the voltage V_{X} of the switching node begins to increase.

As the voltage V_{X} of the switching node increases, a current I_{LS} flowing through the lower power transistor 102 decreases, and a current I_{HS} begins to flow through the upper power transistor 101. Accordingly, a current I_{L} is supplied to an inductor through the upper power transistor 101.

In the transition from the off state to the on state of the upper power transistor 101, a Miller plateau occurs in the upper power transistor 101.

The Miller plateau is one of the characteristics of a power transistor. Parasitic capacitances, such as a gate-source capacitance, a gate-drain capacitance, and a drain-source capacitance of power transistors are one of causes of the Miller plateau. Because the Miller plateau changes depending on various conditions, such as a process, a temperature, an input voltage applied to the power conversion system, and a load current, it may be difficult to determine a Miller plateau voltage.

When the upper power transistor 101 transitions at a relatively very high speed, an EMI may occur in the power conversion system when a current is rapidly supplied to the upper power transistor 101 from a power source. In addition, when the upper power transistor 101 transitions at a relatively very high speed, a shoot-through current may be generated in the lower power transistor 102 that is in an off state, and thus, false turn-on of the lower power transistor 102 may occur. To avoid these problems, the upper power transistor 101 needs to be driven to not transition at a relatively very high speed prior to reaching the Miller plateau. Accordingly, in order to properly control the transition of the upper power transistor 101, the Miller plateau of the upper power transistor 101 may need to be determined.

Referring to FIGS. 1A and 1B, it may be seen that, when the voltage V_{X} of the switching node crosses 0V, a Miller plateau occurs in the upper power transistor 101. Accordingly, the disclosure provides example embodiments of estimating a Miller plateau of a power transistor using a voltage of a switching node of a power conversion system and example embodiments of driving the power transistor based on the estimated Miller plateau.

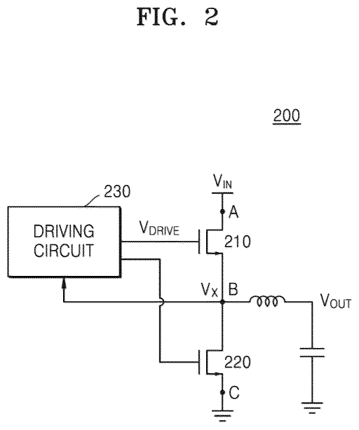

FIG. 2 is a circuit diagram of a power conversion system 200 according to an example embodiment.

The power conversion system 200 is configured to convert an input voltage VIN to an output voltage V_{OUT}. The power conversion system 200 may include a DC-DC converter. For example, the power conversion system 200 may include a buck converter, a boost converter, an inverting converter, or a buck-boost converter, but is not limited thereto.

In an example embodiment, the power conversion system 200 includes a first power transistor 210, a second power transistor 220, and a driving circuit 230.

The first power transistor 210 may be electrically connected to a power source node A and a switching node B. The second power transistor 220 may be electrically connected to the switching node B and a ground node C. The driving circuit 230 may be electrically connected to the switching node B and gate terminals of the first power transistor 210 and the second power transistor 220.

The first power transistor 210 and the second power transistor 220 may include a wide-bandgap (WBG) semiconductor, a metal-oxide-semiconductor field-effect transistor (MOSFET), or an insulated gate bipolar transistor (IGBT), but are not limited thereto. The first power transistor 210 and the second power transistor 220 may include a gallium nitride (GaN) semiconductor or a silicon carbide s (SiC) semiconductor, but are not limited thereto.

In some embodiments, the second power transistor 220 may be replaced with a diode.

The driving circuit 230 may be configured to estimate a Miller plateau of the first power transistor 210. The driving circuit 230 may estimate the Miller plateau of the first power transistor 210 based on the voltage V_{X} of the switching node B. The driving circuit 230 may estimate the Miller plateau of the first power transistor 210 by detecting the voltage V_{X} of the switching node B crossing a predetermined voltage level.

The predetermined voltage level may be 0V. According to another example embodiment, the predetermined voltage level may be substantially 0V. Here, 0V may substantially denote a voltage level that may be regarded as 0V in a power conversion system.

A point at which the voltage V_{X} of the switching node B crosses 0V from negative to positive may be a point at which a Miller plateau occurs in the first power transistor 210, that is, a point at which a gate voltage of the first power transistor 210 reaches the Miller plateau voltage. Accordingly, the driving circuit 230 may estimate the Miller plateau of the first power transistor 210 by detecting the zero crossing of the voltage V_{X} of the switching node B.

When a bias voltage Vbias exists at the switching node B, the predetermined voltage level may be Vbias. The bias voltage Vbias may be a negative or positive voltage. In this case, the point at which the voltage V_{X} of the switching node B crosses the bias voltage Vbias may be the point at which a Miller plateau occurs in the first power transistor 210.

The driving circuit 230 may be configured to drive the first power transistor 210 and the second power transistor 220. The driving circuit 230 may output a drive voltage V_{DRIVE} for driving the first power transistor 210 based on the voltage V_{X} of the switching node B. Also, the driving circuit 230 may control a gate resistance of the second power transistor 220 based on the voltage V_{X} of the switching node B.

The driving circuit 230 may drive the first power transistor 210 so that the gate voltage of the first power transistor 210 increases by a first increment amount prior to the voltage V_{X} of the switching node B crosses the predetermined voltage level. In addition, when the voltage V_{X} of the switching node B crosses the predetermined voltage level, the driving circuit 230 may drive the first power transistor 210 so that the gate voltage of the first power transistor 210 increases by a second increment amount that is greater than the first increment amount.

The driving circuit 230 may drive the first power transistor 210 so that the gate voltage of the first power transistor 210 increases by a first increment amount prior to the voltage V_{X} of the switching node B crosses 0V from negative to positive. In addition, when the voltage V_{X} of the switching node B crosses 0V from negative to positive, the driving circuit 230 may drive the first power transistor 210 so that the gate voltage of the first power transistor 210 increases by a second increment amount that is greater than the first increment amount. Accordingly, the gate voltage of the first power transistor 210 may increase by a first increment amount up to the Miller plateau voltage, and may increase by a second increment amount from the Miller plateau voltage.

Because the transition of the first power transistor 210 is controlled by the driving circuit 230 based on the Miller plateau, the transitioning of the first power transistor 210 at a relatively very high speed may be prevented. Accordingly, the EMI problem and false turn-on problem in the power conversion system may be reduced or prevented.

The driving circuit 230 may reduce the gate resistance of the second power transistor 220 when the voltage V_{X} of the switching node B crosses a predetermined voltage level. In an example embodiment, the driving circuit 230 may reduce the gate resistance of the second power transistor 220 when the voltage V_{X} of the switching node B crosses 0V from negative to positive. Accordingly, the false turn-on of the second power transistor 220 may be prevented.

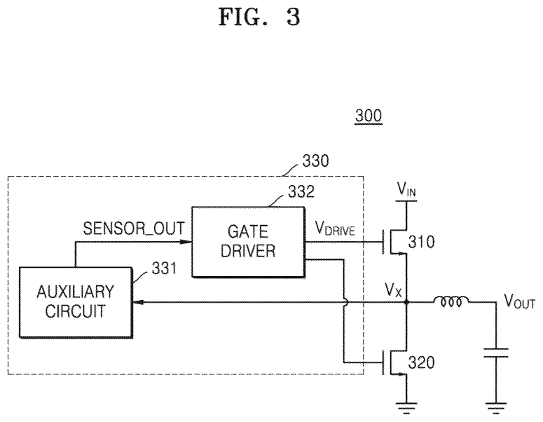

FIG. 3 is a circuit diagram of a power conversion system 300 according to an example embodiment.

In an example embodiment, the power conversion system 300 includes a first power transistor 310, a second power transistor 320, and a driving circuit 330. The description of the power conversion system 200 of FIG. 2 may be applied to the power conversion system 300 of FIG. 3. For convenience of explanation, redundant explanations are omitted.

In an example embodiment, the driving circuit 330 includes an auxiliary circuit 331 and a gate driver 332. The auxiliary circuit 331 may be electrically connected to the switching node and the gate driver 332. The gate driver 332 may be electrically connected to the auxiliary circuit 331 and gate terminals of the first and second power transistors 310 and 320.

The auxiliary circuit 331 may be configured to estimate a Miller plateau of the first power transistor 310. The auxiliary circuit 331 may estimate the Miller plateau of the first power transistor 310 by detecting the voltage V_{X} of the switching node crossing a predetermined voltage level.

An output signal SENSOR_OUT of the auxiliary circuit 331 may be in a low state or high state depending on the detection result. For example, the low state output signal SENSOR_OUT may be a signal of a first voltage level, and the high state output signal SENSOR_OUT may be a signal of a second voltage level higher than the first voltage level.

The auxiliary circuit 331 may change the output signal SENSOR_OUT from a low state to a high state when the voltage V_{X} of the switching node crosses a predetermined voltage level.

In an example embodiment, the auxiliary circuit 331 may change the output signal SENSOR_OUT from a low state to a high state when the voltage V_{X} of the switching node crosses 0V from negative to positive.

The gate driver 332 may be configured to drive the first power transistor 310 and the second power transistor 320. The gate driver 332 may output a drive voltage V_{DRIVE} for driving the first power transistor 310 based on the output signal SENSOR_OUT of the auxiliary circuit 331. Also, the gate driver 332 may control the gate resistance of the second power transistor 320 based on the output signal SENSOR_OUT of the auxiliary circuit 331.

When the output signal SENSOR_OUT of the auxiliary circuit 331 is in a low state, the gate driver 332 may drive the first power transistor 310 so that a gate voltage of the first power transistor 310 increases by a first increment amount. In addition, when the output signal SENSOR_OUT of the auxiliary circuit 331 is in a high state, the gate driver 332 may drive the first power transistor 310 so that the gate voltage of the first power transistor 310 increases by a second increment amount higher than the first increase amount.

In an example embodiment, the output signal SENSOR_OUT of the auxiliary circuit 331 changes from a low state to a high state at a point when the voltage V_{X} of the switching node crosses 0V from negative to positive, that is, when the Miller plateau occurs in the first power transistor 310. Accordingly, the gate voltage of the first power transistor 310 may increase by a first increment amount up to the Miller plateau voltage, and may increase by a second increment amount from the Miller plateau voltage.

Because the transition of the first power transistor 310 is controlled based on the Miller plateau by the gate driver 332, the at a relatively very high speed transition of the first power transistor 310 may be prevented. Accordingly, an EMI problem and a false turn-on problem in the power conversion system may be reduced or prevented.

The gate driver 332 may reduce a gate resistance of the second power transistor 320 when the output signal SENSOR_OUT of the auxiliary circuit 331 changes from a low state to a high state. Accordingly, a false turn-on of the second power transistor 320 may be prevented.

Referring to FIGS. 2 and 3, the power conversion systems 200 and 300 including buck converters according to example embodiments have been described. However, embodiments are not limited to buck converters, and embodiments may be applied to various power conversion systems including any kind of DC-DC converter.

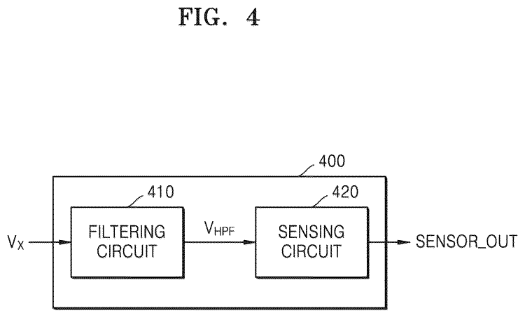

FIG. 4 is a diagram explaining an auxiliary circuit 400 according to an example embodiment.

In an example embodiment, the auxiliary circuit 400 is configured to estimate a Miller plateau of a power transistor of a power conversion system. In an example embodiment, the auxiliary circuit 400 includes a filtering circuit 410 and a sensing circuit 420.

The filtering circuit 410 may be electrically connected to a switching node of the power conversion system. The sensing circuit 420 may be electrically connected to the output node of the filtering circuit 410.

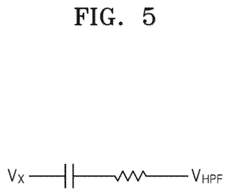

The filtering circuit 410 may be a high pass filter (HPF) configured to filter a voltage V_{X} of a switching node. For example, the filtering circuit 410 may be an HPF including a capacitance and a resistance as shown in FIG. 5.

The sensing circuit 420 may be configured to detect whether the voltage V_{X} of the switching node crosses a predetermined voltage level based on a voltage V_{HPF} of the output node of the filtering circuit 410. Because the voltage V_{HPF} is a high-pass filtered of the voltage V_{X} of the switching node, the voltage V_{HPF} of an output node of the filtering circuit 410 crossing the predetermined voltage level may be the same as the voltage V_{X} of the switching node crossing the predetermined voltage level. Accordingly, the sensing circuit 420 may detect whether the voltage V_{X} of the switching node crosses the predetermined voltage level by detecting the voltage V_{HPF} of the output node of the filtering circuit 410 crossing the predetermined voltage level.

The sensing circuit 420 may output a low state or high state signal SENSOR_OUT depending on the voltage V_{HPF} of the output node of the filtering circuit 410, that is, the voltage V_{X} of the switching node. When the voltage V_{HPF} of the output node of the filtering circuit 410 crosses the predetermined voltage level, that is, when the voltage V_{X} of the switching node crosses the predetermined voltage level, the sensing circuit 420 may change the output signal SENSOR_OUT from a low state to a high state. For example, when the voltage V_{HPF} of the output node of the filtering circuit 410 crosses 0V from negative to positive, that is, if the voltage V_{X} of the switching node crosses 0V from negative to positive, the sensing circuit 420 may change the output signal SENSOR_OUT from a low state to a high state.

The filtering circuit 410 removes low-frequency components or noise of the switching node voltage, allowing the auxiliary circuit 400 to estimate the Miller Plateau more accurately. In the auxiliary circuit 400, the filtering circuit 410 may be an optional component. When the auxiliary circuit 400 does not include the filtering circuit 410, the sensing circuit 420 may be electrically connected to the switching node and configured to directly detect whether the voltage V_{X} of the switching node crosses a predetermined voltage level.

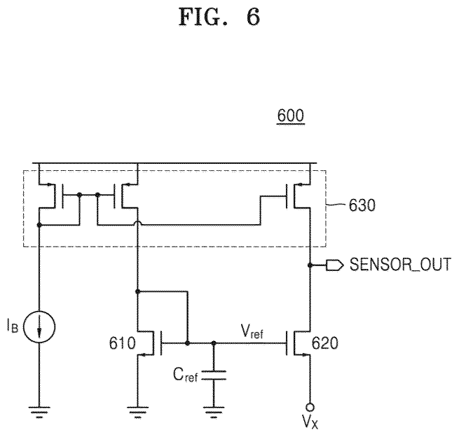

FIG. 6 is a circuit diagram of a sensing circuit 600 according to an example embodiment.

In an example embodiment, the sensing circuit 600 is configured to sense the voltage V_{X} of the switching node crossing 0V from negative to positive. In an embodiment, the sensing circuit 600 includes a first transistor 610 and a second transistor 620.

An emitter terminal of the first transistor 610 may be electrically connected to a ground voltage node. A gate terminal of the first transistor 610 may be electrically connected to a gate terminal of the second transistor 620. Accordingly, a gate voltage Vref of the first transistor 610 and the second transistor 620 may be the same. According to an example embodiment, a capacitor C_{ref} may be used to stabilize the gate voltage Vref of the first transistor 610 and the second transistor 620. An emitter terminal of the second transistor 620 may be electrically connected to a switching node of a power conversion system.

The sizes of the first transistor 610 and the second transistor 620 may be the same. For example, a ratio of a width and a length of the first transistor 610 may be the same as a ratio of a width and a length of the second transistor 620.

The sensing circuit 600 may further include a current source I_{B} and a current mirror circuit 630. An output current of the current source I_{B} may be mirrored by the current mirror circuit 630 and supplied to the first transistor 610 and the second transistor 620.

In an off state of the power transistor, the voltage V_{X} of the switching node may be a negative voltage. In this case, a source voltage of the first transistor 610 may be 0V, and a source voltage of the second transistor 620 may be a negative voltage. Accordingly, a gate-source voltage of the second transistor 620 may be greater than a gate-source voltage of the first transistor 610. A current flowing in the transistor may be proportional to the size of the transistor and the gate-source voltage. Because the gate-source voltage of the second transistor 620 is greater than the gate-source voltage of the first transistor 610, a current flowing through the second transistor 620 may be greater than a current flowing through the first transistor 610. Accordingly, an output signal SENSOR_OUT of the sensing circuit 600 may be in a low state.

When the transition of the power transistor begins from an off state to an on state, the voltage V_{X} of the switching node may begin to increase, and the gate-source voltage of the second transistor 620 may begin to decrease. Then, at the moment when the voltage V_{X} of the switching node crosses zero, the gate-source voltage of the second transistor 620 becomes less than the gate-source voltage of the first transistor 610, and thus, the current flowing through the second transistor 620 may be less than the current flowing through the first transistor 610. Accordingly, the output signal SENSOR_OUT of the sensing circuit 600 may change from a low state to a high state.

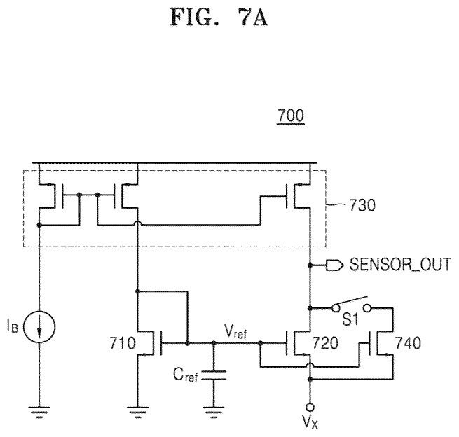

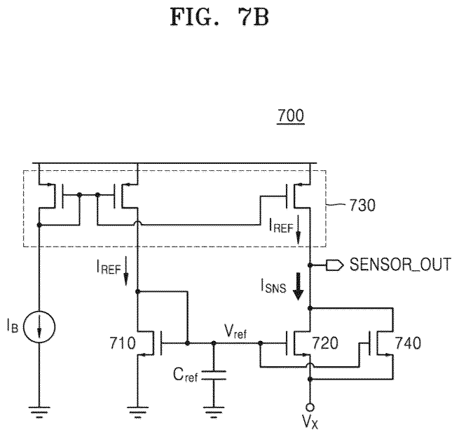

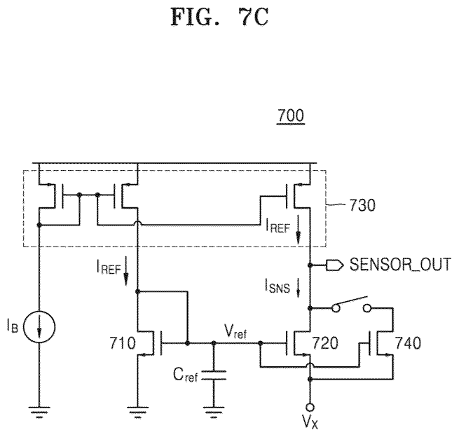

FIGS. 7A to 7C are circuit diagrams of a sensing circuit 700 according to example embodiments.

In an example embodiment, the sensing circuit 700 is configured to sense a voltage V_{X} of a switching node crossing 0V from negative to positive. In an example embodiment, the sensing circuit 700 includes a first transistor 710, a second transistor 720, a third transistor 740, a switch S1, a current source I_{B}, and a current mirror circuit 730. In order to avoid redundant explanation, differences from the sensing circuit 600 of FIG. 6 will be described.

An emitter terminal of the first transistor 710 may be electrically connected to a ground voltage node. A gate terminal of the first transistor 710 may be electrically connected to a gate terminal of the second transistor 720 and a gate terminal of the third transistor 740. Accordingly, a gate voltage Vref of the first transistor 710, the second transistor 720, and the third transistor 740 may be the same. An emitter terminal of the second transistor 720 may be electrically connected to a switching node of the power conversion system and an emitter terminal of the third transistor 740.

The sizes of the first transistor 710 and the third transistor 740 may be the same. For example, a ratio of a width and a length of the first transistor 710 may be the same as a ratio of a width and a length of the third transistor 740.

The size of the second transistor 720 may be less than the size of the first transistor 710 and the third transistor 740. For example, a ratio of a width and a length of the second transistor 720 may be smaller than the ratio of the width and the length of the first transistor 710 and the third transistor 740.

The switch S1 may be electrically connected to a collector terminal of the second transistor 720 and a collector terminal of the third transistor 740. The switch S1 may be configured to control an electrical connection between the collector terminal of the second transistor 720 and the collector terminal of the third transistor 740. The switch S1 may be operated in an on state when a power transistor is in an off state and in an off state when the power transistor is in an on state.

An output current of the current source I_{B} may be mirrored by the current mirror circuit 730 and a current I_{REF} may be supplied to the first to third transistors 710, 720, and 740.

Referring to FIG. 7B, when the power transistor is in an off state, the switch S1 may be in an on state, and the voltage V_{X} of the switching node may be a negative voltage. In this case, the source voltage of the first transistor 710 may be 0V, and the source voltage of the second transistor 720 and the third transistor 740 may be a negative voltage. Accordingly, a gate-source voltage of the second transistor 720 and the third transistor 740 may be greater than a gate-source voltage of the first transistor 710. Because the second transistor 720 and the third transistor 740 are parallel when the switch S1 is in an on state, the total size of the second transistor 720 and the third transistor 740 may be greater than the size of the first transistor 710. Accordingly, a current I_{SNS} flowing through the second transistor 720 and the third transistor 740 becomes greater than a current I_{REF}, and the output signal SENSOR_OUT of the sensing circuit 700 may be in a low state.

Referring to FIG. 70, when a transition from an off state to an on state of the power transistor begins, the switch S1 is in an off state, the voltage V_{X} of the switching node begins to increase, and the gate-source voltage of the second transistor 720 may begin to decrease. Then, at the moment when the voltage V_{X} of the switching node crosses zero, the gate-source voltage of the second transistor 720 becomes less than the gate-source voltage of the first transistor 710, thus, the current I_{SNS} flowing into the second transistor 720 may be less than the current I_{REF}. Accordingly, an output signal SENSOR_OUT of the sensing circuit 700 may change from the low state to the high state.

According to example embodiments, the voltage V_{HPF} of the output node of the filtering circuit crossing a predetermined voltage level may be the same as the voltage V_{X} of the switching node crossing the predetermined voltage level. Accordingly, in the example embodiments of FIGS. 6 to 7C, the switching node may be replaced with the output node of the filtering circuit, and the voltage V_{X} of the switching node may be replaced with the voltage V_{HPF} of the output node of the filtering circuit.

As described above, example embodiments have been disclosed in the drawings and specification. In the specification, the example embodiments are described by using some specific terms, but the terms used are for the purpose of describing the technical scope of the disclosure only and are not intended to be limiting of meanings or the technical scope described in the claims. Therefore, it will be understood by those skilled in the art that various changes in form and details may be made therein without departing from the spirit and scope of the disclosure as defined by the appended claims and their equivalents.

It should be understood that example embodiments described herein should be considered in a descriptive sense only and not for purposes of limitation. Descriptions of features or aspects within each example embodiment should typically be considered as available for other similar features or aspects in other embodiments. While example embodiments have been described with reference to the figures, it will be understood by those of ordinary skill in the art that various changes in form and details may be made therein without departing from the spirit and scope as defined by the following claims and their equivalents.

What is claimed is:

1. An auxiliary circuit configured to estimate a Miller plateau of a power transistor in a power conversion system, the auxiliary circuit comprising:
a filtering circuit electrically connected to a switching node of the power conversion system and configured to filter a voltage of the switching node; and
a sensing circuit electrically connected to an output node of the filtering circuit and configured to detect whether the voltage of the switching node becomes equal to a predetermined voltage level based on a voltage of the output node of the filtering circuit.

2. The auxiliary circuit of claim 1, wherein an output node of the sensing circuit is electrically connected to a gate driver for the power transistor.

3. The auxiliary circuit of claim 1, wherein the sensing circuit is further configured to detect a zero-crossing of the voltage of the switching node.

4. The auxiliary circuit of claim 1, wherein the sensing circuit is further configured to detect a zero-crossing of the voltage of the switching node from a negative direction to a positive direction.

5. The auxiliary circuit of claim 1, wherein the sensing circuit is further configured to output a low state output signal or a high state output signal based on a detection result, and
wherein the sensing circuit is further configured to change the output signal from a low state to a high state based on the voltage of the switching node becoming equal to the predetermined voltage level.

6. The auxiliary circuit of claim 1, wherein the sensing circuit comprises:
a first transistor comprising a first emitter terminal electrically connected to a ground voltage node; and
a second transistor comprising a second emitter terminal electrically connected to the output node of the filtering circuit and a gate terminal electrically connected to the gate terminal of the first transistor.

7. The auxiliary circuit of claim 6, wherein a size of the first transistor is equal to a size of the second transistor.

8. The auxiliary circuit of claim 6, wherein the output node of the sensing circuit is electrically connected to a collector terminal of the second transistor.

9. The auxiliary circuit of claim 6, wherein the sensing circuit further comprises:
a current source; and
a current mirror circuit configured to mirror and supply an output current of the current source to the first transistor and the second transistor.

10. The auxiliary circuit of claim 6, wherein the sensing circuit further comprises a third transistor that comprises a third emitter terminal electrically connected to the output node of the filtering circuit and a gate terminal electrically connected to the gate terminal of the second transistor.

11. The auxiliary circuit of claim 10, wherein a size of the second transistor is less than a size of the first transistor, and
wherein a size of the third transistor is equal to the size of the first transistor.

12. The auxiliary circuit of claim 10, wherein the sensing circuit further comprises a switch configured to control an electrical connection between a collector terminal of the second transistor and a collector terminal of the third transistor.

13. The auxiliary circuit of claim 12, wherein the switch is configured to operate in an on state based on the power transistor being in an off state and to operate in an off state based on the power transistor being in an on state.

14. The auxiliary circuit of claim 1, wherein the filtering circuit comprises a high pass filter configured to filter a voltage of the switching node.

15. A driving circuit for a power conversion system, the driving circuit comprising:
an auxiliary circuit configured to estimate a Miller plateau of a power transistor; and
a gate driver electrically connected to the auxiliary circuit,
wherein the auxiliary circuit comprises:
a filtering circuit electrically connected to a switching node of the power conversion system and configured to filter a voltage of the switching node; and
a sensing circuit electrically connected to an output node of the filtering circuit and configured to detect whether the voltage of the switching node becomes equal to a predetermined voltage level based on the voltage of the output node of the filtering circuit, and
wherein the gate driver is configured to drive the power transistor based on a detection result of the sensing circuit.

16. The driving circuit of claim 15, wherein the sensing circuit is further configured to output a low state output signal or a high state output signal based on the detection result, and
wherein the gate driver is further configured to drive the power transistor based on the output signal of the sensing circuit.

17. The driving circuit of claim 16, wherein the gate driver is further configured to drive the power transistor to increase the gate voltage of the power transistor by a first increment amount based on the output signal of the sensing circuit being in the low state, and to drive the power transistor to increase the gate voltage of the power transistor by a second increment amount greater than the first increment amount based on the output signal of the sensing circuit changing from the low state to the high state.

18. A power conversion system comprising:
a first power transistor and a second power transistor electrically connected to a switching node;
an auxiliary circuit configured to estimate a Miller plateau of the first power transistor; and
a gate driver electrically connected to the auxiliary circuit,
wherein the auxiliary circuit comprises:
a filtering circuit electrically connected to the switching node and configured to filter a voltage of the switching node; and
a sensing circuit electrically connected to an output node of the filtering circuit and configured to detect whether the voltage of the switching node crosses a predetermined voltage level based on the voltage of the output node of the filtering circuit, and
wherein the gate driver is configured to drive the first power transistor and the second power transistor based on a detection result of the sensing circuit.

19. The power conversion system of claim 18, wherein the sensing circuit is further configured to output a low state output signal or a high state output signal based on the detection result, and
wherein the gate driver is further configured to drive the first power transistor based on the output signal of the sensing circuit.

20. The power conversion system of claim 18, wherein the sensing circuit is further configured to output a low state output signal or a high state output signal based on the detection result, and
wherein the gate driver is configured to control a gate resistance of the second power transistor based on the output signal of the sensing circuit.
